(19) United States
(12) Patent Application Publication
(10) Pub. No.: US 2005/0149841 A1
(43) Pub. Date: Jul. 7, 2005

(54) Channel coding/decoding apparatus and method using a parallel concatenated low density parity check code

(75) Inventors: Gyu-Bum Kyung, Seoul (KR); Hong-Sil Jeong, Seo-gu (KR); Jae-Yoel Kim, Gunpo-si (KR)

Correspondence Address: DILWORTH & BARRESE, LLP, 333 EARLE OVINGTON BLVD., UNIONDALE, NY, 11553, US

(73) Assignee: SAMSUNG ELECTRONICS CO., LTD., GYEONGGI-DO (KR)

(21) Appl. No.: 10/988,891

(22) Filed: Nov. 15, 2004

(30) Foreign Application Priority Data
Nov. 14, 2003 (KR) 80741/2003

(51) Int. Cl. G06F 11/00; H03M 13/00

(52) U.S. Cl. 714/800

(57) ABSTRACT

A parallel concatenated low density parity check (LDPC) code having a variable code rate is provided by generating, upon receiving information bits, a first component LDPC code according to the information bits, interleaving the information bits according to a predetermined interleaving rule, and generating a second component LDPC code according to the interleaved information bits. With use of the parallel concatenated LDPC code, a mobile communication system can use a Hybrid Automatic Retransmission Request (HARQ) scheme and an Adaptive Modulation and Coding (AMC) scheme without restriction.

### PRIORITY

This application claims priority under 35 U.S.C. § 119 to an application entitled “Channel Coding/Decoding Apparatus and Method Using A Parallel Concatenated Low Density Parity Check Code” filed in the Korean Intellectual Property Office on Nov. 14, 2003 and assigned Serial No. 2003-80741, the contents of which are incorporated herein by reference.

### BACKGROUND OF THE INVENTION

1. Field of the Invention

The present invention relates generally to a channel encoding/decoding apparatus and method, and in particular, to a channel encoding/decoding apparatus and method using a parallel concatenated Low Density Parity Check (LDPC) code.

2. Description of the Related Art

In communications, it is very important to efficiently and reliably transmit data over a channel. In the next generation multimedia mobile communication system, it is necessary to increase system efficiency using a channel encoding scheme appropriate for the system, as there is a demand for a high-speed communication system capable of processing and transmitting a variety of information, such as image and radio data, beyond that of the early voice-only service.

During data transmission, inevitable errors caused by noise, interference, and fading occur according to channel conditions, thereby causing information loss. In order to reduce the information loss, various error-control schemes are used according to characteristics of channels to increase system reliability. For example, the most typical error-control scheme uses error-correcting codes.

FIG. 1 is a block diagram illustrating a transmitter/receiver of a conventional communication system. Referring to FIG. 1, in a transmitter side, a transmission message ‘u’ is coded by an encoder 101 using a predetermined encoding scheme before being transmitted over a channel. The symbol ‘c’ is modulated by a modulator 103 using a predetermined modulation scheme, and the modulated signal ‘s’ is transmitted to a receiver side over a channel 105.

A signal ‘r’ received at the receiver side is a distorted signal, which is a mixture of the signal ‘s’ transmitted by the transmitter side and various noises caused by a change in channel conditions. The received signal ‘r’ is demodulated by a demodulator 107 using a demodulation scheme corresponding to the modulation scheme used in the modulator 103 of the transmitter side, and the demodulated signal ‘x’ is decoded by a decoder 109 using a decoding scheme corresponding to the encoding scheme used in the encoder 101 of the transmitter side. The decoder 109 outputs the decoded signal û.

In order for the receiver side to decode the signal ‘u’ transmitted by the transmitter side without error, it is necessary to provide a channel encoder and decoder having better performance. In particular, when the channel is a wireless channel, errors caused by the channel are more considerable. The decoder 109 of the transmitter side detects an estimated value of the transmission message using the data received over the channel.

With the rapid progress of mobile communication systems, technology for transmitting a large volume of data at and up to a capacity level presently available in wired networks must be developed for a wireless network. As a high-speed, high-capacity communication system capable of processing and transmitting various information such as image data and radio data, and simple voice service data is required, it is necessary to increase the system transmission efficiency using an appropriate channel encoding scheme in order to improve the system performance. However, a mobile communication system inevitably experiences errors occurring due to noise, interference, and fading according to channel conditions during data transmission. As indicated above, the occurrence of errors causes a loss of information data.

In order to reduce the information data loss, it is possible to improve reliability of the mobile communication system using various error-control schemes. The most popularly used error-control scheme uses an error-correcting code. A description will now be made of a turbo code and a LDPC code, which are typical error correcting codes.

A. Turbo Code

It is well known that the turbo code is superior in performance gain to a convolutional code conventionally used for error correction, during high-speed data transmission. The turbo code is advantageous in that it can efficiently correct an error caused by noises generated in a transmission channel, thereby increasing the reliability of the data transmission.

B. LDPC Code

The LDPC code can be decoded using an iterative decoding algorithm based on a sum-product algorithm on a factor graph. Because a decoder for the LDPC code uses the sum-product algorithm-based iterative decoding algorithm, it is lower in complexity to a decoder for the turbo code. In addition, the decoder for the LDPC code is easily implemented with a parallel processing decoder, when compared with the decoder for the turbo code.

Shannon's channel coding theorem shows that reliable communication is possible only at a data rate not exceeding a channel capacity. However, Shannon's channel coding theorem has proposed no detailed channel encoding/decoding scheme for supporting a data rate up to the maximum channel capacity limit. Generally, although a random code having a very large block size shows performance approximating a channel capacity limit of Shannon's channel coding theorem, when a MAP (Maximum A Posteriori) or ML (Maximum Likelihood) decoding scheme is used, it is actually impossible to implement the decoding scheme because of its heavy calculation load.

The turbo code was proposed by Berrou, Glavieux, and Thitimajshima in 1993, and as indicated above, has superior performance approximating a channel capacity limit of Shannon's channel coding theorem. The proposal of the turbo code triggered active research on iterative decoding and graphical expression of codes, and LDPC codes proposed by Gallager in 1962 have been newly spotlighted in the research.

Cycles exist on a factor graph of the turbo code and the LDPC code, and it is well known that iterative decoding on the factor graph of the LDPC code where cycles exist is suboptimal. Also, it has been experimentally proven that the LDPC code has excellent performance through iterative decoding.

The LDPC code known to have the highest performance ever shows performance having a difference of only about 0.04 [dB] at a channel capacity limit of Shannon's channel coding theorem at a Bit Error Rate (BER) 10⁻⁵, using a block size 10⁷. In addition, although an LDPC code defined in Galois Field (GF) with q>2, i.e., GF(q), increases in complexity in its decoding process, it is much superior in performance to a binary code. However, no satisfactory theoretical description has been provided for successful decoding by an iterative decoding algorithm for the LDPC code defined in GF(q).

The LDPC code, proposed by Gallager, is defined by a parity check matrix in which major elements have a value of 0 and minor elements, except the elements having the value of 0, have a non-zero value, i.e., a value of 1. In the following description, it will be assumed that a non-zero value is a value of 1.

More specifically, a encoding scheme using LDPC codes corresponds to a encoding scheme using block codes, and in this encoding scheme, a calculation is made between transmission data I and a predetermined generative matrix G for encoding. If the coded data is defined as C, the coded data C can be expressed as shown in Equation (1).
I·G=C (1)

When the coded data C is decoded, the coded data C is calculated with the parity check matrix H, and when a calculation result between the parity check matrix H and all coded data C becomes ‘0’ as illustrated in Equation (2), it is determined that there is no error.
H·C=0, ∀C (2)

Therefore, the LDPC code is defined as the parity check matrix H, and complexity of a calculation for the LDPC encoding is also determined by the parity check matrix H.

For example, an (N, j, k) LDPC code is a linear block code having a block length N, and is defined by a sparse parity check matrix in which each column has elements having a value of 1, each row has k elements having a value of 1, and all of the elements except for the elements having the value of 1 have a value of 0.

An LDPC code in which a weight of each column in the parity check matrix is fixed to ‘j’ and a weight of each row in the parity check matrix is fixed to ‘k’ as stated above, is called a “regular LDPC code.” Herein, the “weight” refers to the number of elements having a non-zero value among the elements constituting the generating matrix and parity check matrix. Unlike the regular LDPC code, an LDPC code in which the weight of each column in the parity check matrix and the weight of each row in the parity check matrix is not fixed is called an “irregular LDPC code.” It is generally known that the irregular LDPC code is superior in performance to the regular LDPC code. However, in the irregular LDPC code, because the weight of each column and the weight of each row in the parity check matrix are not fixed, i.e., are irregular, the weight of each column in the parity check matrix and the weight of each row in the parity check matrix must be properly adjusted in order to guarantee the superior performance.

FIG. 2 is a diagram illustrating a parity check matrix of a general (8, 2, 4) LDPC code. Referring to FIG. 2, a parity check matrix H of the (8, 2, 4) LDPC code is comprised of 8 columns and 4 rows, wherein a weight of each column is fixed to 2 and a weight of each row is fixed to 4. Because the weight of each column and the weight of each row in the parity check matrix are regular as stated above, the (8, 2, 4) LDPC code illustrated in FIG. 2 becomes a regular LDPC code.

FIG. 3 is a diagram illustrating a factor graph of the (8, 2, 4) LDPC code illustrated in FIG. 2. Referring to FIG. 3, a factor graph of the (8, 2, 4) LDPC code is comprised of 8 variable nodes of x₁ 300, x₂ 302, x₃ 304, x₄ 306, x₅ 308, x₆ 310, x₇ 312, and x₈ 314, and 4 check nodes 316, 318, 320, and 322. When an element having a value of 1, i.e., a non-zero value, exists at a point where an i^{th} row and a j^{th} column of the parity check matrix of the (8, 2, 4) LDPC code cross each other, a branch is created between a variable node xᵢ and a j^{th} check node.

Because the parity check matrix of the LDPC code has a very small weight as described above, it is possible to perform iterative decoding even in a block code having a relatively long length, that exhibits performance approximating a capacity limit of a Shannon channel, such as a turbo code, while continuously increasing a block length of the block code. MacKay and Neal have proven that an iterative decoding process of an LDPC code using a flow transfer scheme is approximate to an iterative decoding process of a turbo code in performance.

In order to generate a high-performance LDPC code, the following conditions should be satisfied.

(1) Cycles on a Factor Graph of an LDPC Code Should be Considered

The term “cycle” refers to a loop formed by the edges connecting the variable nodes to the check nodes in a factor graph of an LDPC code, and a length of the cycle is defined as the number of edges constituting the loop. A cycle being long in length indicates that the number of edges connecting the variable nodes to the check nodes included in the loop in the factor graph of the LDPC code is large. However, a cycle being short in length indicates that the number of edges connecting the variable nodes to the check nodes included in the loop in the factor graph of the LDPC code is small.

As cycles in the factor graph of the LDPC code become longer, the performance efficiency of the LDPC code increases. That is, when long cycles are generated in the factor graph of the LDPC code, it is possible to prevent performance degradation such as an error floor occurring when too many cycles with a short length exist on the factor graph of the LDPC code.

(2) Efficient Encoding of an LDPC Code Should be Considered

It is difficult for the LDPC code to undergo real-time encoding compared with a convolutional code or a turbo code because of its high encoding complexity. In order to reduce the encoding complexity of the LDPC code, a Repeat Accumulate (RA) code has been proposed. However, the RA code also has a limitation in reducing the encoding complexity of the LDPC code. Therefore, efficient encoding of the LDPC code should be considered.

(3) Degree Distribution on a Factor Graph of an LDPC Code Should be Considered

Generally, an irregular LDPC code is superior in performance to a regular LDPC code, because a factor graph of the irregular LDPC code has various degrees. The term “degree” refers to the number of edges connected to the variable nodes and the check nodes in the factor graph of the LDPC code. Further, the phrase “degree distribution” on a factor graph of an LDPC code refers to a ratio of the number of nodes having a particular degree to the total number of nodes. It has been proved by Richardson that an LDPC code having a particular degree distribution is superior in performance.

As described above, it is well known that the LDPC code, together with the turbo code, is superior in a performance gain for high-speed data transmission, and the LDPC code is advantageous in that it can efficiently correct errors caused by noises generated in a transmission channel, thereby increasing the reliability of the data transmission.

However, the LDPC code is not free in terms of code rate. That is, because the LDPC code has a relatively high code rate, it has a limitation in terms of the code rate. In current LDPC codes, most have a code rate of ½ and only some have a code rate of ⅓. The limitation in code rate exerts a fatal influence on high-speed, high-capacity data transmission. Of course, although a degree distribution representing the best performance can be calculated using a density evolution scheme in order to implement a relatively low code rate for the LDPC code, it is difficult to implement an LDPC code having a degree distribution representing the best performance due to various restrictions, such as a cycle structure on a factor graph and hardware implementation.

In a good channel environment, although codes having high error correcting capability are not used, most errors can be corrected using an Automatic Repeat Request (ARQ) scheme. In the ARQ scheme, an increase in number of error bits decreases information throughput or increases decoding complexity undesirably. However, in a poor channel environment, because signal distortion is considerable, codes having high error correcting capability should be used in order to increase efficiency of the ARQ scheme. In this case, in order to correct errors with fewer retransmissions, codes having powerful error correcting capability are needed.

Because whether the high error correcting capability is needed is determined according to the channel environment as described above, a system having a plurality of codes, rather than a system having one code, is appropriate for the actual wireless channel environment. If an appropriate code is selected for transmission and reception according to the wireless channel environment, it is possible to more efficiently correct errors and increase the information throughput.

As mobile communication systems develop, various transmission schemes such as a Hybrid Automatic Retransmission Request (HARQ) scheme and an Adaptive Modulation and Coding (AMC) scheme are used to increase the efficiency of resources while transmitting a large volume of data.

A communication system utilizing the HARQ scheme must create codes having various code rates using one component code. That is, the HARQ scheme increases its efficiency using soft combining scheme. The soft combining scheme is classified into Chase Combining (CC) scheme and Incremental Redundancy (IR) scheme. In the CC scheme, a transmission side uses the same data for both initial transmission and retransmission. That is, in the CC scheme, if m symbols were transmitted as one coded block at the initial transmission, the same m symbols are transmitted as one coded block even at retransmission. The term “coded block” refers to user data transmitted for one Transmission Time Interval (TTI). That is, in the CC scheme, the same code rate is used for both the initial transmission and retransmission. Then, a reception side soft-combines an initially-transmitted coded block with the retransmitted coded block, and performs a Cyclic Redundancy Check (CRC) operation on the soft-combined coded block to determine if there is an error in the soft-combined coded block.

In the IR scheme, however, a transmission side uses data in different formats for the initial transmission and retransmission. For example, if n-bit user data is channel-coded into m symbols, the transmission side transmits only some of the m symbols at the initial transmission, and sequentially transmits the remaining symbols at retransmission. That is, in the IR scheme, different code rates are used for the initial transmission and retransmission. Then, a reception side configures coded blocks having a high code rate by concatenating retransmitted coded blocks to the end of the initially transmitted coded bocks, and then performs error correction. In the IR scheme, a coded block transmitted at the initial transmission and coded blocks transmitted at the retransmission are identified by their version numbers. For example, a coded block transmitted at initial transmission is assigned a version number #1, a coded block transmitted at first retransmission is assigned a version number #2, and a coded block transmitted at second retransmission is assigned a version number #3. The reception side can soft-combine the initially transmitted coded block with the retransmitted coded block using the version numbers.

The AMC scheme adaptively selects a modulation scheme and a coding scheme used for each channel according to a channel response characteristic of each channel. The term “coding scheme” refers to a scheme for selecting, for example, a code rate. The AMC scheme has a plurality of modulation schemes and a plurality of coding schemes, and modulates and codes a signal by combining the modulation schemes and the coding schemes. Commonly, combinations of the modulation schemes and the coding schemes are called “Modulation and Coding Scheme (MCS),” and can be defined as a plurality of MCSs with level #1 to level #N. That is, the AMC scheme adaptively selects a level of MCS according to a channel response characteristic between a transmission side (or a Base Station (BS)), and a reception side (or a Subscriber Station (SS)), thereby improving system efficiency.

As described above, when the HARQ and AMC schemes are used, it is necessary to support various code rates. However, because the LDPC code has limitations in terms of code rate as described above, it is hard to use the HARQ and AMC schemes for the LDPC code. Accordingly, there is a demand for a channel encoding/decoding scheme capable of supporting various code rates using the LDPC code.

### SUMMARY OF THE INVENTION

It is, therefore, an object of the present invention to provide a channel encoding/decoding apparatus and method using a parallel concatenated LDPC code.

It is another object of the present invention to provide a channel encoding/decoding apparatus and method using a parallel concatenated LDPC code, having low decoding complexity.

It is further another object of the present invention to provide a channel encoding/decoding apparatus and method using a parallel concatenated LDPC code supporting a variable code rate.

In accordance with a first aspect of the present invention, there is provided a channel encoding apparatus using a parallel concatenated low-density parity check (LDPC) code. The channel encoding apparatus includes a first LDPC encoder for generating a first component LDPC code according to information bits received; an interleaver for interleaving the information bits according to a predetermined interleaving rule; and a second LDPC encoder for generating a second component LDPC code according to the interleaved information bits.

In accordance with a second aspect of the present invention, there is provided a channel encoding method using a parallel concatenated low-density parity check (LDPC) code. The channel encoding method includes the steps of generating a first component LDPC code according to information bits received; interleaving the information bits according to a predetermined interleaving rule; and generating a second component LDPC code according to the interleaved information bits.

In accordance with a third aspect of the present invention, there is provided a channel decoding apparatus using a parallel concatenated low-density parity check (LDPC) code having information bits and first and second parity bits corresponding to the information bits. The channel decoding apparatus includes a first LDPC decoder for generating a first component LDPC code upon receiving a signal by decoding information updated during previous decoding, output from a second LDPC decoder, and information bits and first parity bits in the received signal; a first exclusive OR (XOR) operator for subtracting the updated information from a signal output from the first LDPC decoder; an interleaver for interleaving a signal output from the first XOR operator according to a predetermined interleaving rule; the second LDPC decoder for generating a second component LDPC code by decoding a signal output from the interleaver; a second XOR operator for subtracting a signal output from the interleaver from a signal output from the second LDPC decoder; and a deinterleaver for deinterleaving a signal output from the second XOR operator according to a deinterleaving rule corresponding to the interleaving rule, and outputting the deinterleaved signal to the first LDPC decoder and the first XOR operator.

In accordance with a fourth aspect of the present invention, there is provided a channel decoding method using a parallel concatenated low-density parity check (LDPC) code having information bits and first and second parity bits corresponding to the information bits. The channel decoding method includes the steps of generating a first component LDPC code upon receiving a signal by decoding information updated during previous decoding, and information bits and first parity bits in the received signal; subtracting the updated information from the first component LDPC code; interleaving the signal determined by subtracting the updated information from the first component LDPC code according to a predetermined interleaving rule; generating a second component LDPC code by decoding the interleaved signal; subtracting the interleaved signal from the second component LDPC code; and deinterleaving the signal determined by subtracting the interleaved signal from the second component LDPC code according to a deinterleaving rule corresponding to the interleaving rule.

In accordance with a fifth aspect of the present invention, there is provided a method for transmitting a signal in a transmitter of a mobile communication system using a parallel concatenated low density parity check (LDPC) code. The method includes the steps of generating first parity bits upon receiving information bits by generating a first component LDPC code according to the information bits; interleaving the information bits according to a predetermined interleaving rule; generating second parity bits by generating a second component LDPC code according to the interleaved information bits; combining the information bits, the first parity bits and the second parity bits in a first method according to channel state fed back from a receiver, and initial-transmitting the combined bits; and if abnormal transmission of the initial-transmitted bits is detected, combining the information bits, the first parity bits and the second parity bits in a second method according to the channel state, and retransmitting the combined bits.

In accordance with a sixth aspect of the present invention, there is provided a method for receiving a signal in a receiver of a mobile communication system using a parallel concatenated low density parity check (LDPC) code. The method includes the steps of decoding a received signal into a combination of information bits, first parity bits constituting a first component LDPC code corresponding to the information bits, and second parity bits constituting a second component LDPC code corresponding to the information bits in a first method according to a channel state; upon failure to normally decode the received signal, sending a retransmission request for the received signal to a transmitter; and decoding a signal received in response to the retransmission request into a combination of the information bits, the first parity bits and the second parity bits in a second method according to the channel state.

### BRIEF DESCRIPTION OF THE DRAWINGS

The above and other objects, features, and advantages of the present invention will become more apparent from the following detailed description when taken in conjunction with the accompanying drawings in which:

FIG. 1 is a block diagram illustrating a transmitter/receiver of a conventional communication system;

FIG. 2 is a diagram illustrating a parity check matrix of a conventional (8, 2, 4) LDPC code;

FIG. 3 is a diagram illustrating a factor graph of the (8, 2, 4) LDPC code illustrated in FIG. 2;

FIG. 4 is a block diagram illustrating an internal structure of a channel encoding apparatus using a parallel concatenated LDPC code according to an embodiment of the present invention;

FIG. 5 is a block diagram illustrating a channel encoding apparatus using a parallel concatenated LDPC code according to an embodiment of the present invention;

FIG. 6 is a diagram illustrating a parity check matrix when the parallel concatenated LDPC code illustrated in FIG. 5 is regarded as one LDPC code;

FIG. 7 is a diagram illustrating a factor graph of a parallel concatenated LDPC code that uses the same LDPC codes as component codes;

FIG. 8 is a signaling diagram illustrating a process of transmitting and retransmitting data using a parallel concatenated LDPC code in a mobile communication system utilizing a HARQ scheme according to an embodiment of the present invention;

FIG. 9 is a flowchart illustrating a process of transmitting and retransmitting data using a parallel concatenated LDPC code in a mobile communication system utilizing AMC and HARQ schemes according to an embodiment of the present invention;

FIG. 10 is a flowchart illustrating a process of receiving data using a parallel concatenated LDPC code in a mobile communication system utilizing AMC and HARQ schemes according to an embodiment of the present invention; and

FIG. 11 is a diagram illustrating an internal structure of a channel decoding apparatus for decoding a parallel concatenated LDPC code according to an embodiment of the present invention.

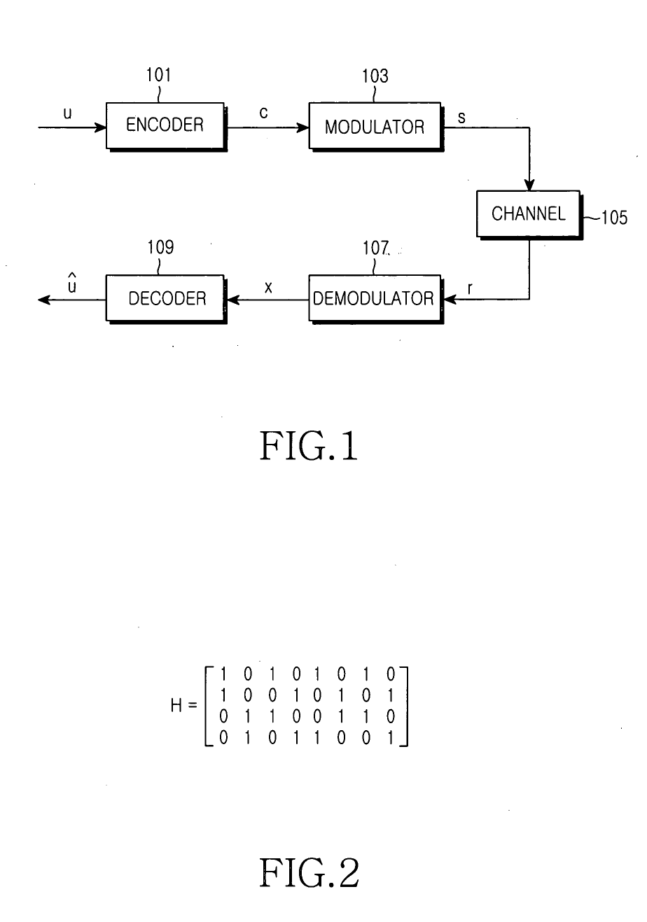

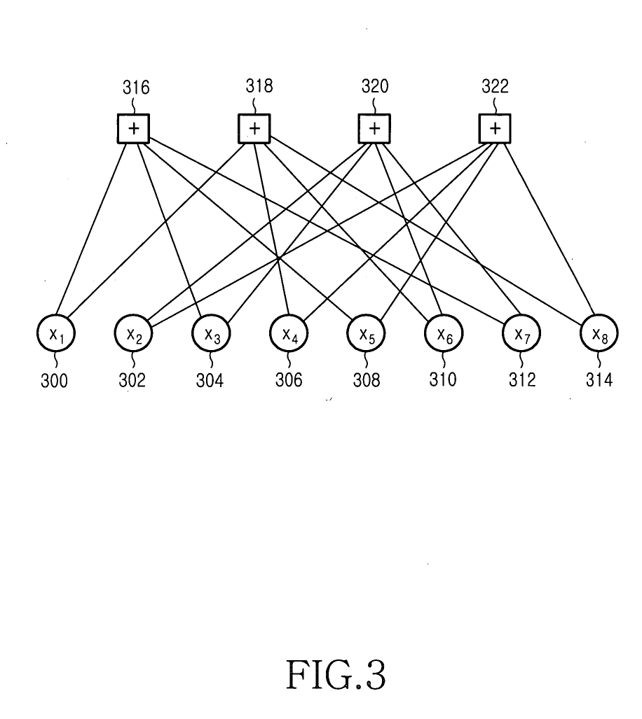

### DETAILED DESCRIPTION OF THE PREFERRED EMBODIMENT

Preferred embodiments of the present invention will now be described in detail herein below with reference to the annexed drawings. In the following description, a detailed description of known functions and configurations incorporated herein has been omitted for conciseness.

The present invention proposes an apparatus and method for encoding/decoding a channel signal using a parallel concatenated Low Density Parity Check (LDPC) code supporting various code rates. In the various schemes proposed to reliably transmit/receive a large volume of data at high speed, such as a Hybrid Automatic Retransmission Request (HARQ) scheme and an Adaptive Modulation and Coding (AMC) scheme, various code rates must be supported.

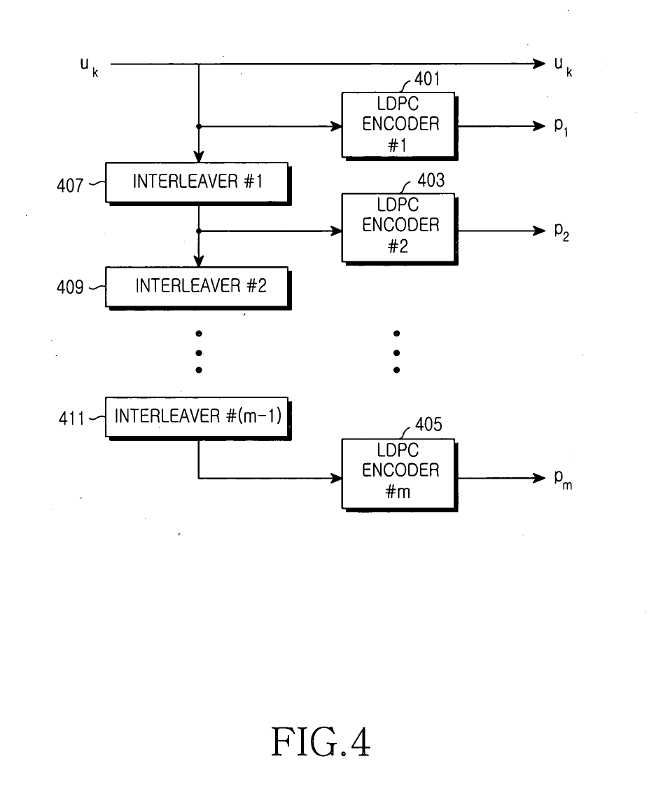

FIG. 4 is a block diagram illustrating an internal structure of a channel encoding apparatus using a parallel concatenated LDPC code according to an embodiment of the present invention. Referring to FIG. 4, the channel encoding apparatus includes a plurality of, for example, m, LDPC encoders of first to m^{th} LDPC encoders 401 to 405, and a plurality of, for example, (m−1), interleavers of first to (m−1)^{th} interleavers 407 to 411, the LDPC encoders being parallel-concatenated to the interleavers. The channel encoding apparatus proposed in the present invention uses a structure for parallel-concatenating an LDPC code like a structure for parallel-concatenating a turbo code, thereby varying a code rate.

Input information bits uₖ are delivered to the first LDPC encoder 401, the first interleaver 407, and an output terminal. The first LDPC encoder 401 generates first parity bits p₁ according to the input information bits uₖ. Because generating the first parity bits p₁ according to the input information bits uₖ by the first LDPC encoder 401 is not directly related to the present invention, a detailed description thereof will be omitted herein. The first interleaver 407 interleaves the information bits uₖ according to a predetermined permutation function, and outputs the interleaved information bits to the second LDPC encoder 403. The second LDPC encoder 403 generates second parity bits p₂ using the signal output from the first interleaver 407.

Third to m^{th} parity bits p₃ to pₘ are generated in the same scheme used for generating the first parity bits p₁ and the second parity bits P₂. That is, the m^{th} parity bits pₘ are generated by interleaving the input information bits uₖ (m−1) times through the first to (m−1)^{th} interleavers 407 to 411 and then LDPC-encoding the interleaved information bits with the m^{th} LDPC encoder 405.

LDPC encoders used for the first to m^{th} LDPC encoders 401 to 405 can be identical to or different from each other in structure. It does not matter if the same LDPC encoders or different LDPC encoders are used, as long as a decoder can decode received data using a decoding scheme corresponding to the encoding scheme used in the LDPC encoders. The first to (m−1)^{th} interleavers 407 to 411 interleave the input information bits uₖ according to the permutation function. Performance of the channel encoding apparatus depends upon implementation of the interleavers. Each of the interleavers connected between the LDPC encoders can be defined as a permutation function, which is used for indicating an information bit of another component code to which a particular information bit of one component code corresponds.

If a code having a code rate of ½ is used for each component code in FIG. 4, the total code rate of the parallel concatenated LDPC code becomes 1/(m+1) as the number of component codes is m. As described above, it is difficult to make the LDPC code such that it has various code rates. However, a parallel concatenated LDPC code proposed in the present invention can be made such that it has various code rates according to a code rate of a component code and the number of concatenated codes. While the turbo code suffers from a decoding delay as several convolutional codes are concatenated to each other, the parallel concatenated LDPC code proposed in the present invention has a short decoding delay.

A detailed description will now be made of a method for implementing a variable code rate of the parallel concatenated LDPC code. As described with reference to FIG. 4, the data bits output from the channel encoding apparatus can be uₖ, p₁, p₂, . . . , pₘ, and a variable code rate can be implemented by appropriately selecting the output data bits. For example, if the information bits uₖ and the first parity bits p₁ are selected and transmitted, a channel encoding apparatus having a code rate of ½ is implemented. If the information bits uₖ, the first parity bits p₁ and the second parity bits P₂ are selected and transmitted, a channel encoding apparatus having a code rate of ⅓ is implemented. Therefore, a channel encoding apparatus having a code rate of 1/m can be implemented by selecting and transmitting the uₖ, p₁, p₂, . . . , pₘ according to the code rate.

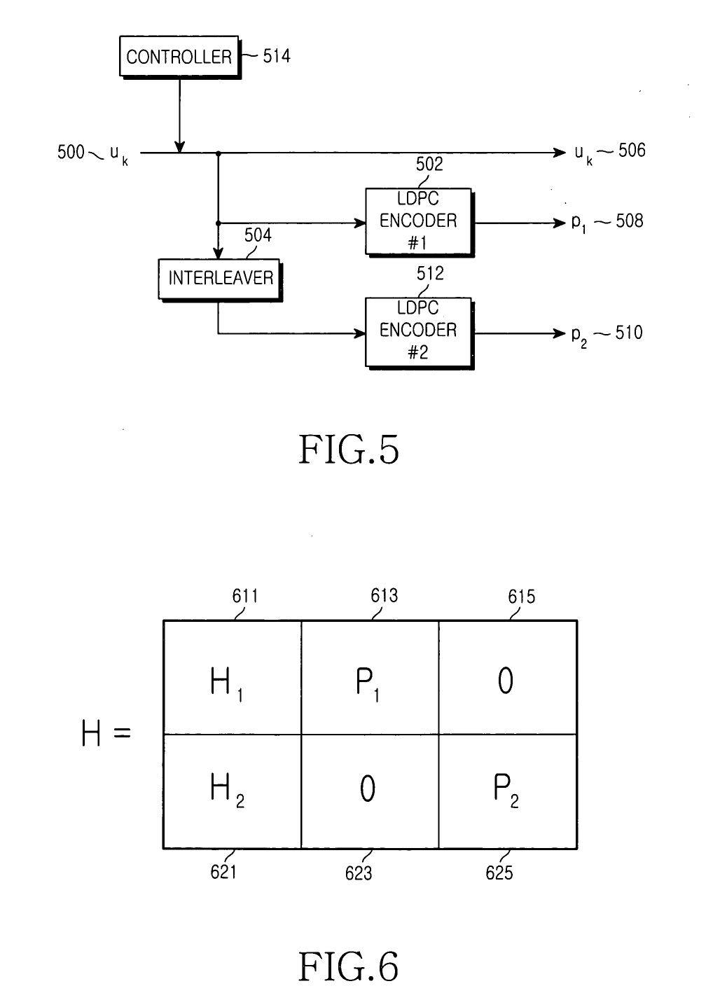

FIG. 5 is a block diagram illustrating a channel encoding apparatus using a parallel concatenated LDPC code according to an embodiment of the present invention. Referring to FIG. 5, the channel encoding apparatus includes a controller 514, an interleaver 504, a first LDPC encoder 502, and a second LDPC encoder 512. The channel encoding apparatus proposed in the present invention is implemented with a structure of parallel-concatenating LDPC codes in the above-described manner, thereby varying a code rate.

Input information bits uₖ (500) are provided to the first LDPC encoder 502, the interleaver 504, and an output terminal. The first LDPC encoder 502 generates first parity bits p₁ (508) according to the input information bits uₖ. Because a process of generating the first parity bits p₁ according to the input information bits uₖ by the first LDPC encoder 502 is not directly related to the present invention, a detailed description thereof will be omitted herein.

The interleaver 504 interleaves the input information bits uₖ according to a predetermined permutation function, and outputs the interleaved information bits to the second LDPC encoder 512. The second LDPC encoder 512 generates second parity bits p₂ (510) using the interleaved signal output from the interleaver 504. Because a process of generating the second parity bits p₂ using the interleaved signal output from the interleaver 504 by the second LDPC encoder 512 is not directly related to the present invention, a detailed description thereof will be omitted herein.

The controller 514 controls an output of the channel encoding apparatus according to a channel condition. For example, when a channel condition is relatively good, the controller 514 performs a control operation such that only the information bits uₖ and the first parity bits p₁ are transmitted. When the channel condition is relatively poor, the controller 514 performs a control operation such that the information bits uₖ and the first parity bits p₁ as well as the second parity bits p₂ are transmitted. By controlling the number of transmission bits in this way, the controller 514 can control a code rate.

Although the present invention has been described with reference to an example in which the controller 514 controls a code rate according to a channel condition, the present invention is also applicable to an example in which the controller 514 controls a code rate in a communication system using the HARQ scheme. The method for controlling a code rate in the communication system using the HARQ scheme will be described in detail below.

FIG. 6 is a diagram illustrating a parity check matrix when the parallel concatenated LDPC code illustrated in FIG. 5 is regarded as one LDPC code. Before a description of FIG. 6 is given, it should be noted that because an LDPC code output from the first LDPC encoder 502 and an LDPC code output from the second LDPC encoder 512 are regarded as different component codes for the parallel concatenated LDPC code described in connection with FIG. 5 and a reception side performs serial decoding on the component codes, decoding performance of the component codes is different from decoding performance of one LDPC code. A difference between an operation of decoding the parallel concatenated LDPC code and an operation of decoding the LDPC code will be described herein below.

Referring to FIG. 6, an LDPC code output from the first LDPC encoder 502 as illustrated in FIG. 5, which is a first component code, can be expressed as H₁ 611 and P₁ 613 of a parity check matrix H illustrated in FIG. 6. In this case, a parity of the LDPC code output from the second LDPC encoder 512, which is a second component code, is padded with 0 615. Herein, an LDPC code output from the first LDPC encoder 502 will be referred to as a “first component LDPC code,” and an LDPC code output from the second LDPC encoder 512 will be referred to as a “second component LDPC code.” H₁ 611 represents a partial matrix corresponding to an information part of the first component LDPC code, and P₁ 613 and 0 615 represent partial matrixes corresponding to a parity part of the first component LDPC code.

In the present invention, only P₁ 613 corresponds to the parity part of the first component LDPC code. Similarly, the LDPC code output from the second LDPC encoder 512, which is the second component code, can be expressed as H₂ 621 and P₂ 625 of the parity check matrix H. In this case, a parity of the LDPC code output from the second LDPC encoder 512, which is the second component code, is padded with 0 623. H₂ 621 represents a partial matrix corresponding to an information part of the second component LDPC code, and 0 623 and P₂ 625 represent partial matrixes corresponding to a parity part of the second component LDPC code. In the present invention, only P₂ 625 corresponds to the parity part of the second component LDPC code.

Because the interleaver 504 interleaves according to a predetermined permutation function as described above, if the permutation function is defined as π₁, the relationship shown in Equation (3) is satisfied.
H₂=π₁H₁ (3)

Although it is not necessary for the first component LDPC code to be identical to the second component LDPC code, it is preferable that they are identical to each other when complexity of a reception side's channel decoder is taken into consideration. Therefore, it is assumed in FIG. 6 that P₁ 613 is identical to P₂ 625.

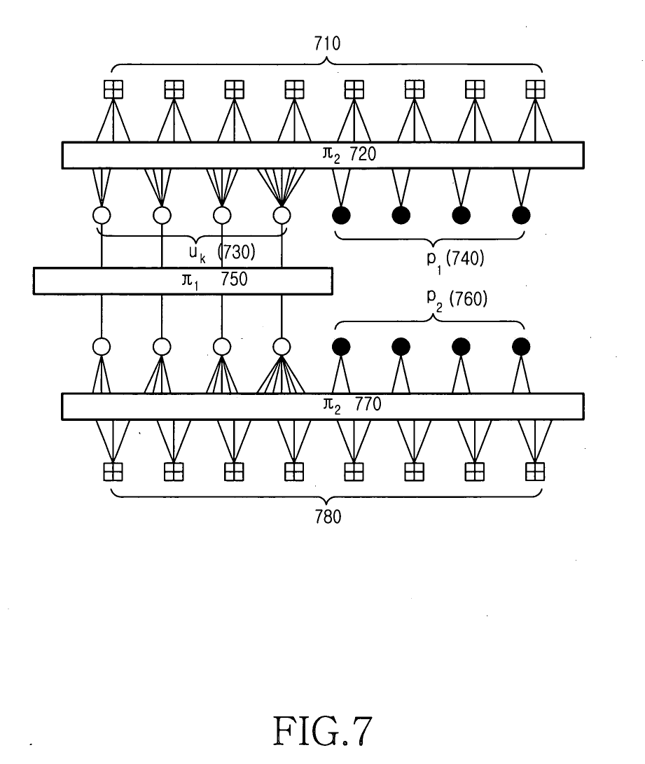

FIG. 7 is a diagram illustrating a factor graph of a parallel concatenated LDPC code that uses the same LDPC codes as the component codes. Referring to FIG. 7, reference numeral 710 denotes check nodes of a first component LDPC code, reference numeral 720 denotes a permutation function π₂ representing a configuration of a factor graph for the first component LDPC code, reference numeral 730 denotes information bits uₖ of the first component LDPC code, and reference numeral 740 denotes first parity bits p₁ of the first component LDPC code. The permutation function π₂ (720) representing a configuration of a factor graph for the first component LDPC code represents how the check nodes are connected to variable nodes, and once the permutation function π₂ (720) is determined, a parity check matrix of the first component LDPC code can be created.

Because a cycle configuration of the factor graph for the first component LDPC code changes according to how the permutation function π₂ (720) is selected, designing the permutation function π₂ (720) is a very important factor in determining performance of the LDPC code. However, because designing the permutation function π₂ (720) for creating an LDPC code having excellent performance is not directly related to the present invention, a detailed description thereof will be omitted herein.

Reference numeral 750 denotes a permutation function π₁ of the interleaver 504 illustrated in FIG. 5, reference numeral 760 denotes second parity bits p₂ of the second component LDPC code, reference numeral 770 denotes a permutation function π₂ representing a configuration of a factor graph for the second component LDPC code, and reference numeral 780 denotes check nodes of the second component LDPC code. Because it is assumed in FIG. 5 that the first LDPC encoder 502 is identical to the second LDPC code 512, the permutation function π₂ (770) representing a configuration of the factor graph of the second component LDPC code is also identical to the permutation function π₂ (720) representing a configuration of the factor graph of the first component LDPC code.

As described with reference to FIG. 7, a factor graph of the parallel concatenated LDPC code has a configuration in which only two component LDPC codes are connected between information bits through an interleaver. Therefore, iterative decoding can be performed in a serial decoding scheme such that a part corresponding to the first component LDPC code is first decoded and when a value of a variable node corresponding to an information part of the first component LDPC code is provided through an interleaver, a part corresponding to the second component LDPC code is decoded.

In a wireless communication system, because power resources of a Base Station (BS) or a Subscriber Station (SS) are limited, it is impossible to transmit signals with maximum transmission power in order to prevent a communication error. As described above, the HARQ and AMC schemes are transmission schemes introduced to perform efficient communication using limited power. Further, the communication system using the HARQ scheme retransmits defective data according to a channel environment using a channel encoding apparatus having various code rates for the defective data.

As described above, a code rate of the parallel concatenated LDPC code can vary according to which component LDPC code is to be selected and how many component LDPC codes will be concatenated. The parallel concatenated LDPC code whose code rate can vary is very suitable for the communication system using the HARQ scheme.

In a digital communication system, because power of a base station and a subscriber station is limited, it is not possible to transmit a signal with infinitely high power in order to perform communication without error. Therefore, the HARQ scheme is needed to communicate without error using the limited power. The HARQ scheme retransmits a defective data block in a channel according to channel conditions using a channel encoding apparatus having a variable code rate. The HARQ scheme is advantageous in that it can obtain a coding gain using additionally received parity bits, and also obtain a combining gain by soft-combining retransmitted information bits with previously received information bits.

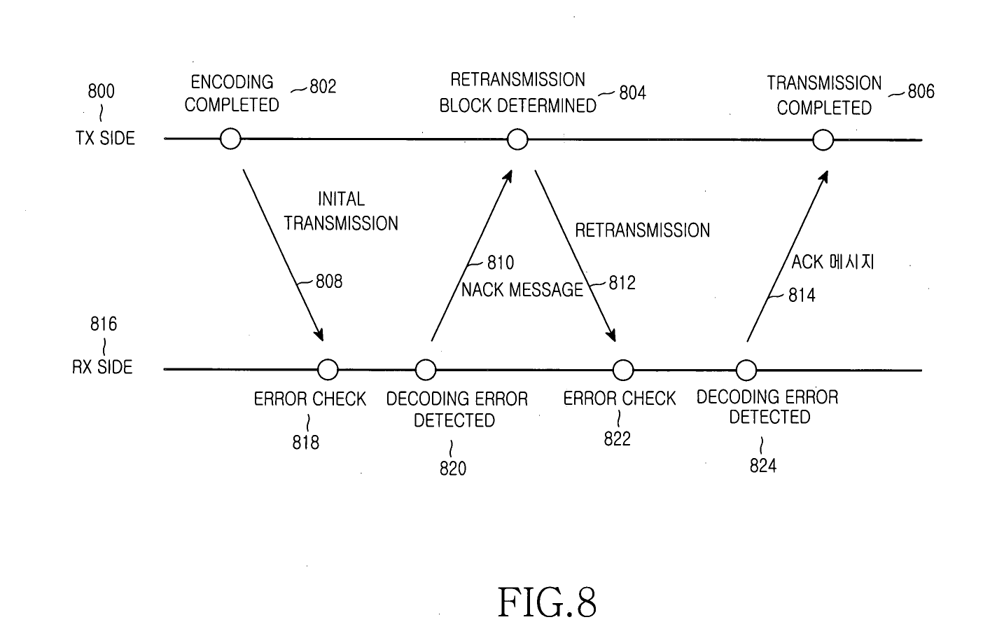

FIG. 8 is a signaling diagram illustrating a process of transmitting and retransmitting data using a parallel concatenated LDPC code in a mobile communication system utilizing a HARQ scheme according to an embodiment of the present invention. Referring to FIG. 8, if a transmission side 800 codes transmission data through a channel encoding apparatus using a parallel concatenated LDPC code according to an embodiment of the present invention at Step 802 and initially-transmits the coded data to a reception side 816 at Step 808. The reception side 816 receives the signal initial-transmitted by the transmission side 800 and determines if there, is an error in the received initial-transmitted signal at Step 818.

The reception side 816 determines if there is an error in the received initial-transmitted signal by making a calculation between the received signal and a parity check matrix H of the parallel concatenated LDPC code as described above. If it is determined that there is an error in the initial-transmitted signal at Step 820, the reception side 816 makes a retransmission request by transmitting a NACK (Negative Acknowledgement) message to the transmission side 800 at Step 810. Upon receiving the NACK message from the reception side 816, the transmission side 800 determines a retransmission block according to a code rate given based on a predetermined HARQ retransmission rule at Step 804.

Because the channel encoding apparatus using a parallel concatenated LDPC code according to an embodiment of the present invention can variably set a code rate for transmission, it can perform retransmission using a code rate higher than the code rate used at initial transmission at Step 812.

Upon receiving the retransmitted data from the transmission side 800, the reception side 816 again determines if there is an error in the retransmitted data at Step 822. If it is determined that there is no error in the retransmitted data at Step 824, the reception side 816 transmits an ACK (Acknowledgement) message to the transmission side 800 at Step 814, thereby completing a data transmission procedure at Step 806. This process is repeated until there is no error detected in the received signal. While a retransmission block is being determined, a code rate is decreased and a combining gain is used, thereby preventing infinite occurrences of the ACK signal.

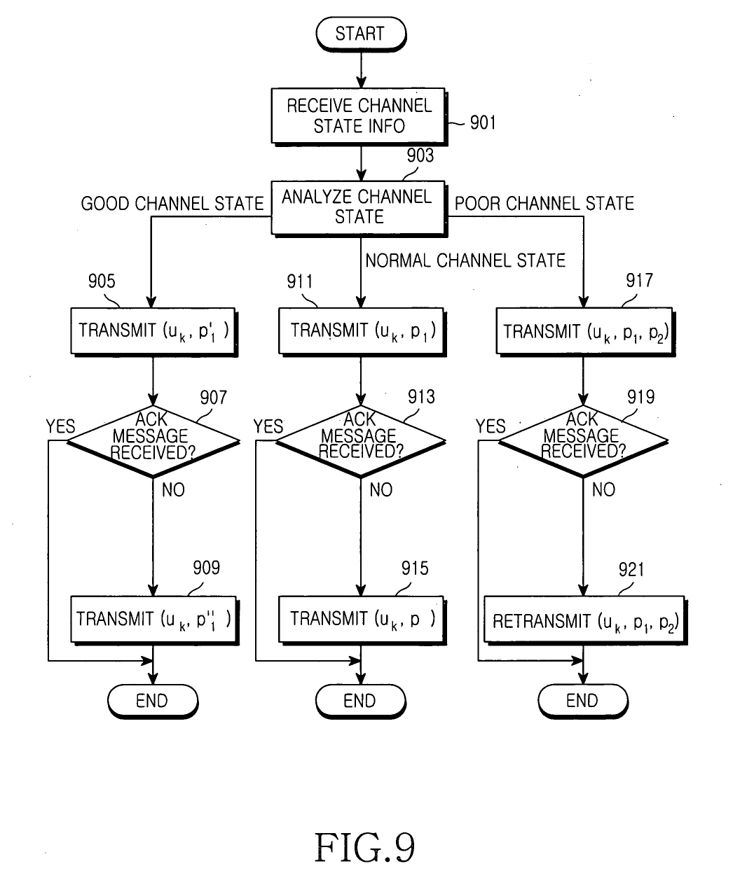

FIG. 9 is a flowchart illustrating a process of transmitting and retransmitting data using a parallel concatenated LDPC code in a mobile communication system employing AMC and HARQ schemes according to an embodiment of the present invention. Referring to FIG. 9, a transmission side periodically receives channel state information at Step 901, and analyzes current channel state information at Step 903. Accordingly, the transmission side can appropriately change a modulation scheme and a code rate according to the channel state information. If the current channel state is good, it is preferable for the transmission side to code data at a relatively low code rate before transmission. Therefore, the transmission side transmits, to a reception side, information bits uₖ and a signal acquired by puncturing first parity bits p₁ in the output signal of the channel encoding apparatus using a parallel concatenated LDPC code described in connection with FIG. 5 at Step 905. In this case, the transmission side does not transmit second parity bits p₂ output from a second component code, and a signal acquired by puncturing a part of the first parity bits p₁ will be referred to as p₁′.

For example, if an LDPC code with a code rate of ½ is used as a first component code and ½ of the first parity bits p₁ is punctured, the total code rate of the channel encoding apparatus using a parallel concatenated LDPC code becomes ⅔. Accordingly, when the channel state is relatively good, the transmission side increases a code rate for transmission of coded data, thereby increasing resource efficiency. When the transmission side fails to receive an ACK message from the reception side due to an error although it transmitted the coded data at Step 907, the transmission side should perform a retransmission operation as it uses the HARQ scheme. In this case, because the channel state is relatively excellent, the transmission side retransmits the information bits uₖ and a part acquired by excluding the part p₁′ punctured at the initial transmission from the first parity bits p₁ at Step 909. Herein, the part acquired by excluding the p₁′ from the first parity bits p₁ will be referred to as p₁″.

However, if the current channel state is poor as a result of the channel state analysis at Step 903, it is preferable for the transmission side to code data at a high code rate before transmission. Therefore, the transmission side transmits all of the output signals of the channel encoding apparatus using a parallel concatenated LDPC code described in FIG. 5, i.e., transmits all of the information bits uₖ, the first parity bits p₁, and the second parity bits p₂ at Step 917. For example, when two component codes are generated using an LDPC encoder having a code rate of ½, a parallel concatenated LDPC code with the total code rate of ⅓ can be generated. If the transmission side fails to receive an ACK message from the reception side due to an error although it transmitted the coded data at Step 919, the transmission side should perform a retransmission operation as it uses the HARQ scheme. In this case, because the channel state is poor, it is preferable for the transmission side to retransmit all of the information bits uₖ, the first parity bits p₁ and the second parity bits p₂, which were transmitted at the initial transmission.

However, if the current channel state is normal as a result of the channel state analysis at Step 903, the transmission side is allowed to transmit only the information bits uₖ and the first parity bits p₁ at the initial transmission at Step 911. If the transmission side fails to receive an ACK message from the reception side due to an error at Step 913, the transmission side should perform a retransmission operation as it uses the HARQ scheme. In this case, because the channel state is normal, it is preferable for the transmission side to retransmit the information bits uₖ, and the second parity bits P₂ at Step 915.

In FIG. 9, the transmission side analyzes the current channel state into three channel states: good channel state, normal channel state, and poor channel state. Whether the current channel state is a good channel state, a normal channel state, or a poor channel state can be determined using a threshold indicating a reference channel state previously set by a mobile communication system. Because a process of determining the threshold is not directly related to the present invention, a detailed description thereof will be omitted herein.

In addition, in FIG. 9, if the transmission side fails to receive an ACK message from the reception side after transmitting a signal, the transmission side determines that it should retransmit the transmitted signal. Also, if the transmission side receives a NACK message from the reception side after transmitting a signal, the transmission side determines that it should retransmit the transmitted signal.

As described with reference to FIG. 9, when the AMC and HARQ schemes are used, the parallel concatenated LDPC code proposed in the present invention can be used. That is, it is possible to efficiently use the AMC and HARQ schemes by variably setting a code rate of the parallel concatenated LDPC code proposed in the present invention.

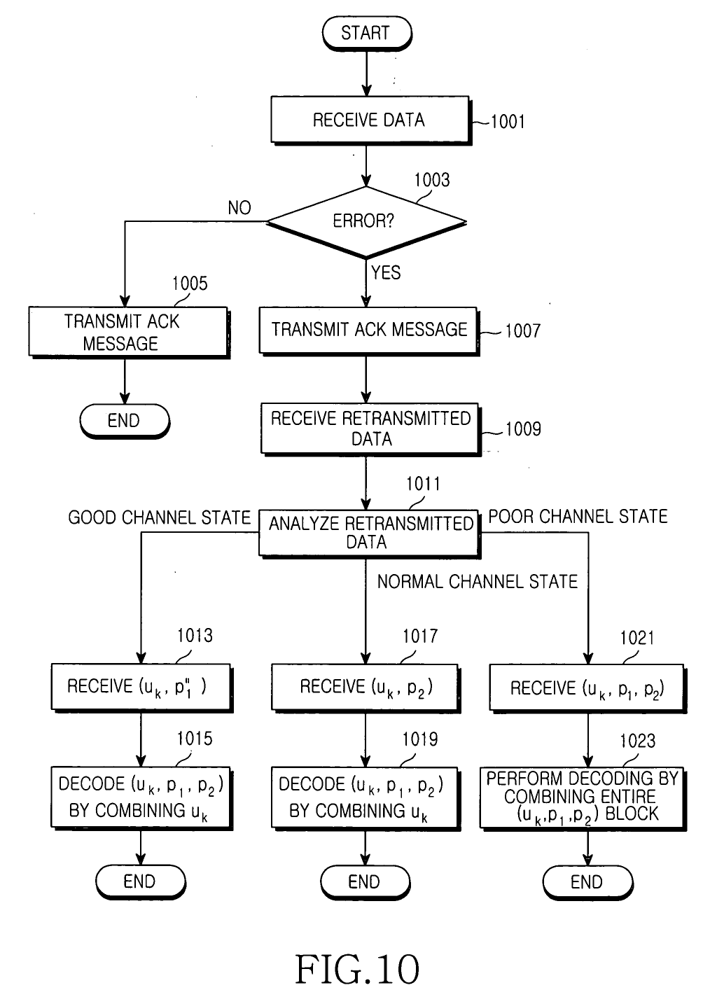

FIG. 10 is a flowchart illustrating a process of receiving data using a parallel concatenated LDPC code in a mobile communication system utilizing AMC and HARQ schemes according to an embodiment of the present invention. Referring to FIG. 10, a reception side receives data from a transmission side at Step 1001, and determines if there is an error in the received data at Step 1003. If it is determined that the data was normally received without error, the reception side transmits an ACK message to the transmission side at Step 1005, to inform the transmission side of normal receipt of the data.

However, if it is determined that there is an error in the received data, the reception side should again receive the data from the transmission side. Therefore, the reception side transmits a NACK message, or a retransmission request signal, to the transmission side at Step 1007. The reception side may not transmit a NACK message to the transmission side or transmit no ACK message to the transmission side within a predetermined time, thereby enabling the transmission side to determine that the message transmitted by the transmission side has not normally arrived at the reception side.

If retransmitted data is received from the transmission side in response to the retransmission request at Step 1009, the reception side decodes the received data according to the current channel state. When the HARQ and AMC schemes are used as described in connection with FIG. 9, a code rate of the data transmitted at the initial transmission can be different from a code rate of the data transmitted at the retransmission according to the channel state at Step 1011.

Therefore, the reception side decodes the transmitted data according to the current channel state using the modulation scheme and the code rate used in the transmission side.

More specifically, if the current channel state is good as a result of the channel state analysis, because the transmission side, as described with reference to FIG. 9, transmits information bits uₖ and a signal p₁′ acquired by puncturing first parity bits p₁ at initial transmission and transmits the information bits uₖ and a part p₁″ acquired by puncturing the p₁′ from the first parity bits p₁ at retransmission, the reception side receives the retransmitted bits uₖ and p₁″ at Step 1013, and decodes uₖ, p₁ and p₂ using the received uₖ and p₁″ at Step 1015. An operation of decoding uₖ, p₁ and p₂ using the uₖ and p₁″ will be described below.

As described above, because the transmission side transmits uₖ and p₁″ at initial transmission and transmits uₖ and p₁″ at retransmission, the reception side can completely decode the uₖ and p₁, and because the transmission side dose not transmit the second parity bits p₂ at both initial transmission and retransmission, an erasure process is performed on the second parity bits p₂. The term “erasure process” refers to a process in which the reception side sets a log likelihood ratio (LLR) to ‘0’ before performing a decoding operation.

However, if the current channel state is normal as a result of the channel state analysis, because the transmission side, as described with reference to FIG. 9, transmits the information bits uₖ and the first parity bits p₁ at initial transmission and transmits the information bits uₖ and the second parity bits p₂ at retransmission, the reception side receives the retransmitted bits uₖ and p₂ at Step 1017, and decodes uₖ, p₁ and p₂ by combining the received retransmitted information bits uₖ with the received initial-transmitted information bits uₖ at Step 1019.

However, if the current channel state is poor as a result of the channel state analysis, because the transmission side, as described with reference to FIG. 9, transmits the information bits uₖ, the first parity bits p₁ and the second parity bits p₂ at both initial transmission and retransmission, the reception side receives the retransmitted bits uₖ, p₁ and p₂ at Step 1021, and decodes uₖ, p₁ and p₂ by combining the received retransmitted bits uₖ, p₁ and p₂ with the received initial-transmitted bits uₖ, p₁ and p₂ at Step 1023. In this case, only the information bits uₖ are combined, and an entire block (uₖ, p₁, p₂) acquired by binding the uₖ with the p₁ and p₂ undergoes serial iterative decoding. Accordingly, the reception side can acquire a combining gain in the combined uₖ block and acquire a coding gain by decoding the p₁ and p₂ together.

As described above, when a parallel concatenated LDPC code according to the present invention is used, it is possible to construct a code having a variable code rate according to which component LDPC code is to be selected and how many component LDPC codes will be concatenated. Therefore, it is possible to efficiently handle a change in channel conditions and acquire a combining gain. Therefore, the parallel concatenated LDPC code is very suitable for the communication system using the HARQ scheme capable of acquiring a combing gain.

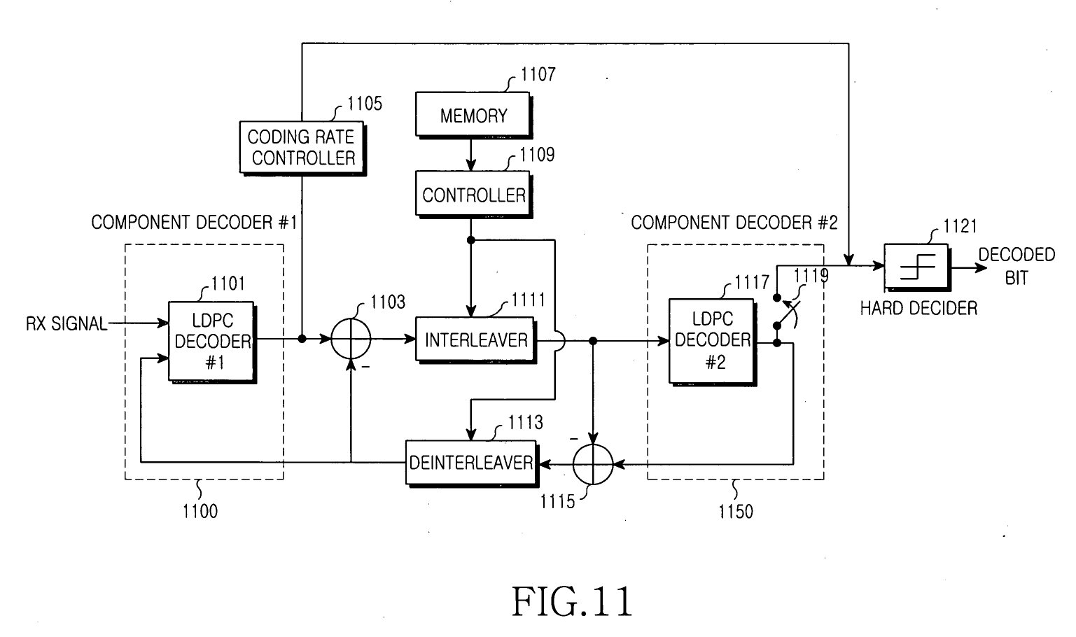

FIG. 11 is a diagram illustrating an internal structure of a channel decoding apparatus for decoding a parallel concatenated LDPC code according to an embodiment of the present invention. Referring to FIG. 11, the channel decoding apparatus for decoding a parallel concatenated LDPC code includes a first component decoder 1100, a first exclusive OR (XOR) operator 1103, a code rate controller 1105, an interleaver 1111, a controller 1109, a memory 1107, a deinterleaver 1113, a second XOR operator 1115, a second component decoder 1150, and a hard decider 1121.

The first component decoder 1100 includes a first LDPC decoder 1101, and the second component decoder 1150 includes a second LDPC decoder 1117 and a switch 1119.

Information bits uₖ and first parity bits p₁ in a signal received over a wireless channel are input to the first LDPC decoder 1101 in the first component decoder 1100. Simultaneously, information updated during previous decoding, output from the second LDPC decoder 1117, is also input to the first LDPC decoder 1101. If the current decoding process is an initial decoding process, the updated information does not exist. In this case, only the information bits uₖ and first parity bits p₁ are input to the first LDPC decoder 1101.

The first LDPC decoder 1101 decodes the input information bits uₖ and first parity bits p₁ and the information updated during previous decoding, output from the second LDPC decoder 1117, and outputs the decoding result to the first XOR operator 1103 and the code rate controller 1105.

The first XOR operator 1103 subtracts the information updated during previous decoding, output from the second LDPC decoder 1117, from the signal output from the first LDPC decoder 1101, and outputs the subtraction result to the interleaver 1111. The controller 1109 reads a permutation function previously stored in the memory 1107, and outputs the read permutation function to the interleaver 1111 and the deinterleaver 1113 such that the interleaver 1111 and the deinterleaver 1113 perform an interleaving operation and a deinterleaving operation according to the permutation function. The interleaver 1111 interleaves the signal output from the first XOR operator 1103 according to the permutation function, and outputs the interleaved signal to the second LDPC decoder 1117 in the second component decoder 1150 and the second XOR operator 1115.

The second LDPC decoder 1117 decodes the signal output from the interleaver 1111, and outputs the decoded signal to the switch 1119. Only the information bits uₖ and second parity bits p₂ are input to the second LDPC decoder 1117. After the iterative decoding a predetermined number of times, the switch 1119 is switched on to provide the signal output from the second LDPC decoder 1117 to the hard decider 1121. Herein, as described above, the switch 1119 can be switched on such that the second LDPC decoder 1117 is connected to the hard decider 1121 after iterative decoding a predetermined number of times. Alternatively, the switch 1119 can be switched on such that the second LDPC decoder 1117 is connected to the hard decider 1121 each time the iterative decoding operation is completed.

In the latter case, the decoding apparatus can perform parity check and use the parity check result as a criterion for determining whether to stop the iterative decoding. The code rate controller 1105 determines whether to use both of or any one of the first LDPC decoder 1101 and the second LDPC decoder 1117 according to a code rate. Herein, the code rate controller 1105 determines whether to use both of or any one of the first LDPC decoder 1101 and the second LDPC decoder 1117 according to a code rate used in a channel encoding apparatus corresponding to the channel decoding apparatus.

As can be understood from the foregoing description, the present invention enables data transmission/reception without restriction of a code rate using a parallel concatenated LDPC code. More specifically, the present invention uses a parallel concatenated LDPC code having a variable code rate in a system utilizing the HARQ and AMC schemes, thereby increasing reliability of data transmission/reception and enabling flexible data transmission/reception.

While the present invention has been shown and described with reference to certain preferred embodiments thereof, it will be understood by those skilled in the art that various changes in form and details may be made therein without departing from the spirit and scope of the present invention as defined by the appended claims.

1. A channel encoding apparatus using a parallel concatenated Low Density Parity Check (LDPC) code, comprising:
a first LDPC encoder for generating a first component LDPC code according to information bits received;
an interleaver for interleaving the information bits according to a predetermined interleaving rule; and
a second LDPC encoder for generating a second component LDPC code according to the interleaved information bits.

2. The channel encoding apparatus of claim 1, further comprising a controller for combining the information bits, the first component LDPC code having first parity bits corresponding to the information bits, and the second component LDPC code having second parity bits corresponding to the information bits, according to a predetermined code rate.

3. A channel encoding method using a parallel concatenated Low Density Parity Check (LDPC) code, comprising the steps of:
generating a first component LDPC code according to information bits received;
interleaving the information bits according to a predetermined interleaving rule; and
generating a second component LDPC code according to the interleaved information bits.

4. The channel encoding method of claim 3, further comprising the step of combining the information bits, the first component LDPC code having first parity bits corresponding to the information bits, and the second component LDPC code having second parity bits corresponding to the information bits, according to a predetermined code rate.

5. A channel decoding apparatus using a parallel concatenated Low Density Parity Check (LDPC) code having information bits, first parity bits corresponding to the information bits, and second parity bits corresponding to the information bits, comprising:
a first LDPC decoder for generating a first component LDPC code by decoding information updated during a previous decoding, and information bits and first parity bits in the received signal;
a first exclusive OR (XOR) operator for subtracting the updated information from a signal output from the first LDPC decoder;
an interleaver for interleaving a signal output from the first XOR operator according to a predetermined interleaving rule;
a second LDPC decoder for generating a second component LDPC code by decoding a signal output from the interleaver;
a second XOR operator for subtracting a signal output from the interleaver from a signal output from the second LDPC decoder; and
a deinterleaver for deinterleaving a signal output from the second XOR operator according to a deinterleaving rule corresponding to the interleaving rule, and outputting the deinterleaved signal to the first LDPC decoder and the first XOR operator,
wherein the information updated during the previous decoding is received from the second LDPC decoder.

6. The channel decoding apparatus of claim 5, further comprising a controller for controlling the interleaving rule and the deinterleaving rule.

7. The channel decoding apparatus of claim 5, further comprising a code rate controller for outputting an output of one of the first LDPC decoder and the second LDPC decoder as final decoded bits according to a predetermined code rate.

8. A channel decoding method using a parallel concatenated Low Density Parity Check (LDPC) code having information bits, first parity bits corresponding to the information bits, and second parity bits corresponding to the information bits, comprising the steps of:
receiving a signal;
generating a first component LDPC code by decoding information updated during a previous decoding, and information bits and first parity bits in the received signal;
subtracting the updated information from the first component LDPC code;
interleaving a signal determined by subtracting the updated information from the first component LDPC code according to a predetermined interleaving rule;
generating a second component LDPC code by decoding the interleaved signal;
subtracting the interleaved signal from the second component LDPC code; and
deinterleaving the signal determined by subtracting the interleaved signal from the second component LDPC code according to a deinterleaving rule corresponding to the interleaving rule.

9. The channel decoding method of claim 8, further comprising the step of outputting one of the first component LDPC code and the second component LDPC code as final decoded bits according to a predetermined code rate.

10. A method for transmitting a signal in a transmitter of a mobile communication system using a parallel concatenated Low Density Parity Check (LDPC) code, comprising the steps of:
receiving information bits;
generating first parity bits by generating a first component LDPC code according to the information bits;
interleaving the information bits according to a predetermined interleaving rule;
generating second parity bits by generating a second component LDPC code according to the interleaved information bits;
combining the information bits, the first parity bits and the second parity bits in a first method according to channel state fed back from a receiver;
initially-transmitting the combined bits; and
if an abnormal transmission of the initially-transmitted bits is detected, combining the information bits, the first parity bits and the second parity bits in a second method according to the channel state, and retransmitting the combined bits.

11. The method of claim 10, wherein when the channel state is a first channel state, the first method combines the information bits with bits acquired by puncturing predetermined bits from the first parity bits.

12. The method of claim 11, wherein when the channel state is the first channel state, the second method combines the information bits with remaining bits obtained by excluding bits acquired by puncturing predetermined bits from the first parity bits.

13. The method of claim 10, wherein when the channel state is a second channel state, the first method combines the information bits with the first parity bits.

14. The method of claim 13, wherein when the channel state is the second channel state, the second method combines the information bits with the second parity bits.

15. The method of claim 10, wherein when the channel state is a third channel state, the first method combines the information bits with the first parity bits and the second parity bits.

16. The method of claim 15, wherein when the channel state is the third channel state, the second method combines the information bits with the first parity bits and the second parity bits.

17. A method for receiving a signal in a receiver of a mobile communication system using a parallel concatenated Low Density Parity Check (LDPC) code, comprising the steps of:
decoding a received signal into a combination of information bits, first parity bits included in a first component LDPC code corresponding to the information bits, and second parity bits included in a second component LDPC code corresponding to the information bits in a first method according to a channel state;
upon failure to normally decode the received signal, sending a retransmission request for the received signal to a transmitter; and
decoding a signal received in response to the retransmission request into a combination of the information bits, the first parity bits and the second parity bits in a second method according to the channel state.

18. The method of claim 17, wherein when the channel state is a first channel state, the first method combines the information bits with bits acquired by puncturing predetermined bits from the first parity bits.

19. The method of claim 18, wherein when the channel state is the first channel state, the second method combines the information bits with remaining bits obtained by excluding bits acquired by puncturing predetermined bits from the first parity bits.

20. The method of claim 17, wherein when the channel state is a second channel state, the first method combines the information bits with the first parity bits.

21. The method of claim 20, wherein when the channel state is the second channel state, the second method combines the information bits with the second parity bits.

22. The method of claim 17, wherein when the channel state is a third channel state, the first method combines the information bits with the first parity bits and the second parity bits.

23. The method of claim 22, wherein when the channel state is the third channel state, the second method combines the information bits with the first parity bits and the second parity bits.
